(19) United States
(12) Patent Application Publication
(10) Pub. No.: US 2019/0088703 A1
(43) Pub. Date: Mar. 21, 2019

(54) METHOD FOR MANUFACTURING A CAMERA AND A CAMERA

(71) Applicant: Robert Bosch GmbH, Stuttgart (DE)

(72) Inventor: Martin Reiche, Weil Der Stadt (DE)

(21) Appl. No.: 16/130,737

(22) Filed: Sep. 13, 2018

(30) Foreign Application Priority Data
Sep. 19, 2017 (DE) 102017216573.1

(51) Int. Cl. H01L 27/146

(52) U.S. Cl. CPC H01L 27/14627; H01L 27/14685; H01L 27/14687; H01L 27/14632

(57) ABSTRACT

A method for manufacturing a camera. The method includes providing and connecting. In the providing, a wafer element, which includes a microlens unit and an image sensor, and a barrel element, which includes a lens system for concentrating light, are provided. In the connecting, the wafer element is connected to the barrel element to manufacture the camera.

### RELATED APPLICATION INFORMATION

The present application claims priority to and the benefit of German patent application no. 10 2017 216 573.1, which was filed in Germany on Sep. 19, 2017, the disclosure which is incorporated herein by reference.

### FIELD OF THE INVENTION

The present invention is directed toward a device or a method for manufacturing a camera and a camera.

### BACKGROUND INFORMATION

Cameras, which have a completely pre-assembled, “fixed focus” objective, may be used in vehicles. This objective is made up of multiple optical elements, such as lenses, aperture, IR filter, which are mounted in a tube, also called a “barrel,” with a fixed position relative to one another. This objective may be delivered by a supplier for a camera assembly, e.g. manufactured and pre-tested as a sub-assembly. In camera manufacturing, this barrel may be very precisely mounted using diverse alignment methods with respect to the optical features of the objective, focal range, and the position of the image sensor.

In the smartphone world, so-called “wafer level optics,” “WLO” for short, have entered in. Optical wafers are applied on a wafer of image sensors and only then separated. The technology hits its limits when complex optical systems, including autofocus and image stabilizing, are to be manufactured and large sensor formats are to be provided. Complex liquid lenses possibly offer new prospects here.

### SUMMARY OF THE INVENTION

Against this background, a method for manufacturing a camera using the approach presented here and a camera according to the main claims are introduced. Advantageous refinements of and improvements on the device indicated in the independent claim are possible due to the measures specified in the dependent claims.

The advantages achievable using the presented approach consist in that a camera is manufacturable, using a method introduced here, which has as one component a wafer element, which is manufacturable quickly and advantageously in large quantities, and as a second component a barrel element, which may be selected specifically for the demands on the camera to be manufactured. As a whole, a complex camera is thus created which is still easily manufacturable.

A method for manufacturing a camera is introduced. The method includes a step of providing and a step of connecting. In the step of providing, a wafer element, which includes a microlens unit and an image sensor, and a barrel element, which includes a lens system for concentrating light, are provided. In the step of connecting, the wafer element is connected to the barrel element to manufacture the camera.

The camera may have very small dimensions, for example in the range of a few millimeters or micrometers. The wafer element, or “wafer level optics” may also be designated as a micro-optical imaging element, which is suited, for example, in particular for use in small cameras. The barrel element is understood to be a so-called “barrel,” whose optical components are situated in a tube with positions fixed relative to one another. The microlens unit may have at least one optical lens, which may be a few nanometers, a few micrometers, or a few millimeters in size. The image sensor may be a semiconductor-based sensor.

In order to be able to provide the wafer element, the method may additionally include a step of manufacturing, in which the wafer element is manufactured. In the step of manufacturing, an optical wafer, which includes a plurality of microlens units situated in a plane, may be connected to a semiconductor wafer, which includes a plurality of image sensors situated in a plane, and a wafer composite thus generated may be separated in order to manufacture the at least one wafer element. A wafer element generated in this way and characterized by only two layers is robustly manufacturable, in particular also during separating. A wafer may be understood to be a disk made from a semiconductor material. The semiconductor wafer and the optical wafer may represent manufactured elements using known methods from semiconductor technology.

To increase a complexity of the camera, the wafer element may be provided in the step of providing in which the microlens unit includes a plurality of microlenses situated in a stack. To this end, a corresponding optical wafer including the microlens units, which each have a plurality of micro lenses situated in a stack, may be used in the step of manufacturing.

For the same reason, the barrel element may also be provided in the step of providing, in which the lens system includes a plurality of lenses situated in a stack, or a corresponding semiconductor wafer including the lens systems, which each have a plurality of lenses situated in a stack, may already be used in the step of manufacturing.

It is additionally advantageous if, in the step of connecting, the wafer element is glued to the barrel element. This creates a simple and yet solid way for connecting the components. If, according to one specific embodiment of the method in the step of providing, the barrel element is provided in which a barrel element edge has a gap, this may function as an adhesive gap. The gap may, for example, be formed as a recess circumferencing the barrel element. Alternatively in the step of providing, the wafer element may also be provided in which a wafer element edge has a gap. This gap may also be formed as a recess circumferencing the wafer element edge.

In the step of providing, the wafer element may be provided which includes an aperture. Thus, the camera may be aligned and connected during manufacturing in the area of the aperture.

To protect the wafer element from dust or other dirt particles, a planar optical element, which is configured to cover a surface of the wafer element, may be inserted between the wafer element and the barrel element in the step of connecting. The optical element may be, for example, an IR filter.

A camera includes a wafer element and a barrel element. The wafer element includes a microlens unit and an image sensor. The barrel element is connected to the wafer element and includes a lens system for concentrating light.

Such a camera may be manufactured using the method in one of the previously presented variants. The camera may function as a substitute for known cameras, the presented camera advantageously having both an advantageously manufacturable wafer element and an attached barrel element, and thus implements a complex camera system.

Exemplary embodiments of the approach presented here are depicted in the figures and explained in greater detail in the subsequent description.

### BRIEF DESCRIPTION OF THE DRAWINGS

FIG. 1 shows a camera according to one exemplary embodiment.

FIG. 2 shows a flow chart of a method for manufacturing a camera according to one exemplary embodiment.

### DETAILED DESCRIPTION

In the subsequent description of advantageous exemplary embodiments of the present approach, the same or similar reference numerals are used for similarly acting elements depicted in the different figures, a repeated description of these elements being omitted.

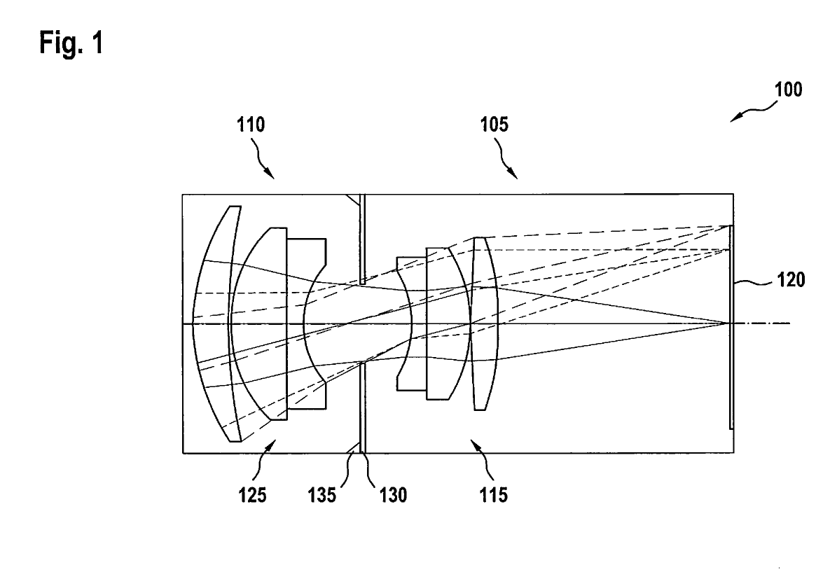

FIG. 1 shows a camera 100 according to one exemplary embodiment. Camera 100 includes a wafer element 105 and a barrel element 110. Wafer element 105 includes a microlens unit 115 and an image sensor 120. Barrel element 110 is connected to wafer element 105 and includes a lens system 125 for concentrating light.

The subsequently described features of camera 100 are optional:

According to this exemplary embodiment, microlens unit 115 includes a plurality of micro lenses situated in a stack. Lens system 125 also includes a plurality of lenses situated in a stack according to this exemplary embodiment.

In addition, wafer element 105 includes an aperture 130 according to this exemplary embodiment.

Wafer element 105 is glued to barrel element 110. For this purpose, a barrel element edge of barrel element 110 includes a circumferential adhesive gap 135 in which an adhesive agent is situated which fixes barrel element 110 on aperture 130.

In addition, an optional, planar optical element, which is configured to cover a surface of wafer element 105, is inserted between wafer element 105 and barrel element 110.

Details of camera 100 are subsequently described again in greater detail according to different exemplary embodiments:

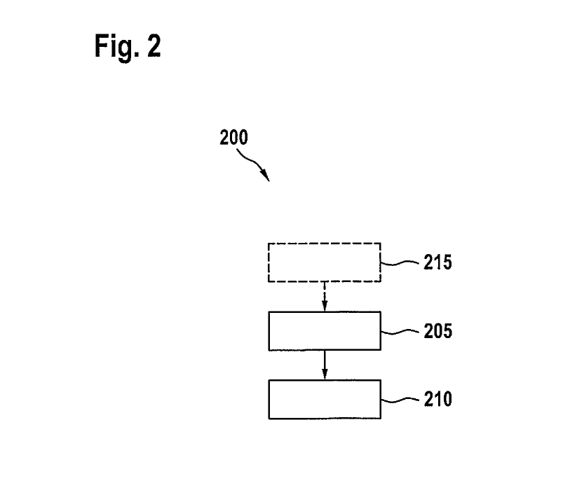

Presently, a camera design is described and subsequently in FIG. 2, a corresponding manufacturing principle is described, which links the advantages of a wafer level optics to an alignment method, which meets the demands on an automotive camera. Camera 100 presented here may also be designated as a camera design with separated objective WLO/barrel with an interposed alignment gap.

In presented camera 100, the optical path is divided into two assemblies. The first assembly in this exemplary embodiment in the form of wafer element 105 includes the optical elements from aperture 130 up to the image point generation on an optical plane in the form of image sensor 120. This first assembly is manufactured in WLO technology on an optical wafer. The optical wafer was connected to the semiconductor wafer. A transversal alignment was carried out with high precision, e.g., using markers on the wafers. An axial alignment was carried out using thick film process tolerance. A separation of these connected wafers into subcameras was then carried out.

The second assembly according to this exemplary embodiment in the form of barrel element 110 includes the optical elements from the entry of the beams into the objective up to aperture 130. This second assembly is conventionally manufactured in a stack including a barrel which mechanically matches the contours of wafer element 105.

In the camera manufacturing, an active alignment was carried out using the separated subcameras, the alignment connecting barrel element 110 to wafer element 105 axially using circumferential adhesive gap 135 in the area of aperture 130. An in situ focusing is then carried out as in the active alignment. An initial curing of the adhesive using UV flash is then carried out and a final, thermal through-hardening in a subsequent furnace step.

According to this exemplary embodiment, the lenses of lens system 125 are made from glass in the barrel assembly in the form of barrel element 110 and thus lens 1, being the outer lens, is depicted as scratch-resistant.

At an adhesion point between wafer element 105 and barrel element 110, the planar optical element is inserted according to this exemplary embodiment, which is already provided in the path; according to this exemplary embodiment, this optical element is an IR filter, also referred to as an IR cutoff. This IR cutoff and/or, according to an alternative exemplary embodiment, another element resting on aperture 130 ensures that the separated subcamera represents a system sealed with respect to dust, whose optical entry surface is easy to clean. Thus, the separated subcameras may simply be transferred from a semiconductor manufacture and finished in a camera assembly.

Wafer element 105 is formed according to this exemplary embodiment in such a way that it satisfies image sensor 120 used, i.e., an adjustment of the chief range angle (CR) is carried out according to the demand on the microlenses of microlens unit 115 and/or a design of the image circle.

Barrel element 110 is configured application-specifically, i.e. an adjustment of the field of view (FOV) is carried out according to the functional demands. Thus, the separated subcamera in the form of wafer element 105 is largely standardized and an identical part, barrel element 110, covers the functional complexity.

FIG. 2 shows a flow chart of a method 200 for manufacturing a camera according to one exemplary embodiment. This may be a camera described by way of FIG. 1.

Method 200 includes a step 205 of providing and a step 210 of connecting. In step 205 of providing, a wafer element, which includes a microlens unit and an image sensor, and a barrel element, which includes a lens system for concentrating light, are provided. In step 210 of connecting, the wafer element is connected to the barrel element to create the camera.

Optionally, method 200 additionally includes a step 215 of manufacturing, in which the wafer element is manufactured, in step 215 of the manufacturing, an optical wafer, which includes a plurality of microlens units situated in a plane, being connected to a semiconductor wafer, which includes a plurality of image sensors situated in a plane, and a wafer composite thus generated is separated in order to manufacture the at least one wafer element.

According to this exemplary embodiment, in step 205 of providing, the wafer element is provided, in which the microlens unit includes a plurality of microlenses situated in a stack. In addition, according to this exemplary embodiment, in step 205 of providing, the barrel element is provided, in which the lens system includes a plurality of lenses situated in a stack. In step 205 of providing, the wafer element is additionally provided according to this exemplary embodiment, which includes an aperture. According to this exemplary embodiment, the barrel element is ultimately provided in step 205 of providing, in which a barrel element edge optionally has a gap.

In step 210 of connecting, the wafer element is glued to the barrel element according to this exemplary embodiment. In addition, according to this exemplary embodiment in step 210 of connecting, a planar optical element, which is configured to cover a surface of the wafer element, is inserted between the wafer element and the barrel element.

If an exemplary embodiment includes an “and/or” linkage between one first feature and one second feature, this is to be read in such a way that the exemplary embodiment according to one specific embodiment includes both the first feature and the second feature, and according to another specific embodiment includes either only the first feature or only the second feature.

What is claimed is:

1. A method for manufacturing a camera, the method comprising:
providing a wafer element, which includes at least one microlens unit and one image sensor, and a barrel element, which includes at least one lens system for concentrating light; and
connecting the wafer element to the barrel element to manufacture the camera.

2. The method of claim 1, further comprising:
in the providing of the wafer element, manufacturing an optical wafer, which includes a plurality of microlens units situated in a plane, connected to a semiconductor wafer, which includes a plurality of image sensors situated in a plane, and a wafer composite thus generated is separated to manufacture the wafer element.

3. The method of claim 1, wherein in the providing, the wafer element is provided in which the microlens unit includes a plurality of microlenses situated in a stack.

4. The method of claim 1, wherein in the providing, the barrel element is provided in which the lens system includes a plurality of lenses situated in a stack.

5. The method of claim 1, wherein in the connecting, the wafer element is glued to the barrel element.

6. The method of claim 1, wherein in the providing, the wafer element includes an aperture.

7. The method of claim 1, wherein in the providing, the barrel element is provided in which a barrel element edge has a gap.

8. The method of claim 1, wherein in the connecting, a planar optical element, which is configured to cover a surface of the wafer element, is inserted between the wafer element and the barrel element.

9. A camera, comprising:
a wafer element which includes at least one microlens unit and one image sensor; and
a barrel element, which is connected to the wafer element and includes at least one lens system for concentrating light.
